(19) United States
(12) Patent Application Publication
(10) Pub. No.: US 2026/0204897 A1
(43) Pub. Date: Jul. 16, 2026

(54) REVERSE CURRENT PROTECTION CIRCUIT

(71) Applicant: ANPEC ELECTRONICS CORPORATION, HSINCHU (TW)

(72) Inventor: SHIH-CHUNG WEI, HSINCHU (TW)

(21) Appl. No.: 19/180,088

(22) Filed: Apr. 15, 2025

(30) Foreign Application Priority Data
Jan. 16, 2025 (TW) 114101743

(51) Int. Cl. H02H 9/02; H03K 17/082

(52) U.S. Cl. CPC H02H 9/025; H03K 17/0822; H03K 2217/0027; H03K 2217/0036; H03K 2217/0063; H03K 2217/0072

(57) ABSTRACT

A reverse current protection circuit is applicable to a high-side switch and a low-side switch. A first terminal of the high-side switch is coupled to an input voltage. A first terminal of the low-side switch is connected to a second terminal of the high-side switch. The reverse current protection circuit detects the input voltage received by the first terminal of the high-side switch and an output voltage of a second terminal of the low-side switch, and accordingly controls the low-side switch. Before a reverse current being larger than a reverse current threshold flows from the output voltage of the second terminal of the low-side switch sequentially through the low-side switch and the high-side switch to the input voltage, the reverse current protection circuit turns off the low-side switch.

### CROSS-REFERENCE TO RELATED PATENT APPLICATION

This application claims the benefit of priority to Taiwan Patent Application No. 114101743, filed on Jan. 16, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a protection circuit, and more particularly to a reverse current protection circuit.

### BACKGROUND OF THE DISCLOSURE

When an output voltage of an electronic device is higher than an input voltage, a reverse current having a large current value sequentially flows to an input power source through the electronic device such that the input power source is damaged. In order to prevent the input power source from being damaged by the reverse current, a conventional reverse current protection circuit is disposed in the electronic device. The conventional reverse current protection circuit includes a Schottky diode configured to block the reverse current from flowing to the input power source. However, power consumption of the Schottky diode of the conventional reverse current protection circuit is increased with an increase in an output current of the electronic device. As a result, the electronic device has high power consumption.

### SUMMARY OF THE DISCLOSURE

In response to the above-referenced technical inadequacies, the present disclosure provides a reverse current protection circuit. The reverse current protection circuit is applicable to a high-side switch and a low-side switch. A first terminal of the high-side switch is coupled to an input voltage. A control terminal of the high-side switch is coupled to a high-side charging voltage. A first terminal of the low-side switch is connected to a second terminal of the high-side switch. The reverse current protection circuit includes a main reverse current protecting circuit. The main reverse current protecting circuit is connected to a control terminal of the low-side switch. The main reverse current protecting circuit is configured to detect the input voltage received by the first terminal of the high-side switch and an output voltage of a second terminal of the low-side switch. The main reverse current protecting circuit is configured to control the low-side switch according to the input voltage and the output voltage. Before a reverse current being larger than a reverse current threshold flows from the output voltage of the second terminal of the low-side switch sequentially through the low-side switch and the high-side switch to the input voltage, the main reverse current protecting circuit turns off the low-side switch.

As described above, the present disclosure provides the reverse current protection circuit. When the input voltage is removed from the first terminal of the high-side switch such that the first terminal of the high-side switch is floating or a short circuit occurs in an input power source used to supply the input voltage, the reverse current protection circuit of the present disclosure appropriately switches the low-side switch. The reverse current being larger than the reverse current threshold is prevented from flowing from the output voltage of the second terminal of the low-side switch sequentially through the low-side switch and the high-side switch to the input power source connected to the first terminal of the high-side switch. Therefore, a reverse current protection effect where the input power source is prevented from being damaged by the reverse current is achieved. In particular, when the reverse current protection effect is achieved, power consumption of the reverse current protection circuit of the present disclosure is much lower than that of conventional reverse current protection circuits.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a circuit diagram of a reverse current protection circuit according to a first embodiment of the present disclosure;

FIG. 2 is a circuit diagram of a reverse current protection circuit according to a second embodiment of the present disclosure;

FIG. 3 is a circuit diagram of a reverse current protection circuit according to a third embodiment of the present disclosure;

FIG. 4 is a circuit diagram of a reverse current protection circuit according to a fourth embodiment of the present disclosure;

FIG. 5 is a circuit diagram of a reverse current protection circuit according to a fifth embodiment of the present disclosure;

FIG. 6 is a circuit diagram of a reverse current protection circuit according to a sixth embodiment of the present disclosure;

FIG. 7 is a circuit diagram of a main reverse current protecting circuit included in a reverse current protection circuit according to a seventh embodiment of the present disclosure; and

FIG. 8 is a waveform diagram of signals of the reverse current protection circuit according to the first to seventh embodiments of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

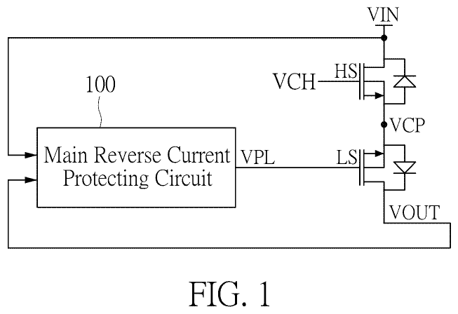

Reference is made to FIG. 1, which is a circuit diagram of a reverse current protection circuit according to a first embodiment of the present disclosure.

As shown in FIG. 1, in the first embodiment, the reverse current protection circuit of the present disclosure includes a main reverse current protecting circuit 100, which is applicable to a switch circuit including a high-side switch HS and a low-side switch LS.

A first terminal of the high-side switch HS is coupled to an input voltage VIN, or is connected to an input power source and receives the input voltage VIN from the input power source. A control terminal of the high-side switch HS is coupled to a high-side charging voltage VCH. A first terminal of the low-side switch LS is connected to a second terminal of the high-side switch HS. A second terminal of the low-side switch LS is used as an output terminal of the switch circuit. A voltage of the second terminal of the low-side switch LS is used as an output voltage VOUT of the switch circuit.

The main reverse current protecting circuit 100 is connected to the first terminal of the high-side switch HS and a control terminal of the low-side switch LS. The main reverse current protecting circuit 100 detects a voltage of the first terminal of the high-side switch HS and the output voltage VOUT of the second terminal of the low-side switch LS.

The main reverse current protecting circuit 100, according to the voltage of the first terminal of the high-side switch HS and the output voltage VOUT of the second terminal of the low-side switch LS, outputs a low-side main control signal VPL to the control terminal of the low-side switch LS for controlling or modulating an operation of the low-side switch LS, for example, modulating an on-time of the low-side switch LS.

It is worth noting that, the main reverse current protecting circuit 100 determines whether or not a reverse current is generated according to the voltage of the first terminal of the high-side switch HS and the output voltage VOUT of the second terminal of the low-side switch LS. Before the reverse current being larger than a reverse current threshold flows from the output voltage VOUT of the second terminal of the low-side switch LS sequentially through the low-side switch LS and the high-side switch HS to the input power source used to supply the input voltage VIN, the main reverse current protecting circuit 100 turns off the low-side switch LS.

For example, when the main reverse current protecting circuit 100 determines that the input voltage VIN is removed from the first terminal of the high-side switch HS such that the first terminal of the high-side switch HS is floating, a short circuit occurs in the input power source used to supply the input voltage VIN or the input voltage VIN is a zero value, the main reverse current protecting circuit 100 determines that the reverse current is generated. Under this condition, the main reverse current protecting circuit 100 turns off the low-side switch LS. As a result, the reverse current being larger than the reverse current threshold is prevented from flowing from the output voltage VOUT of the second terminal of the low-side switch LS sequentially through the low-side switch LS and the high-side switch HS to the input power source used to supply the input voltage VIN. Therefore, the input power source is prevented from being damaged by the reverse current.

That is, the reverse current protection circuit of the present disclosure is capable of maintaining normal operations of the high-side switch HS and the low-side switch LS for continually supplying the output voltage VOUT having an appropriate voltage value to a load connected to a node between the first terminal of the low-side switch LS and the second terminal of the high-side switch HS.

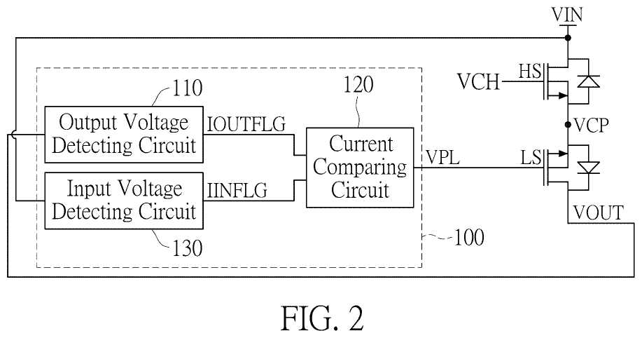

Reference is made to FIG. 2, which is a circuit diagram of a reverse current protection circuit according to a second embodiment of the present disclosure.

As shown in FIG. 2, in the second embodiment, the main reverse current protecting circuit 100 of the reverse current protection circuit of the present disclosure includes an output voltage detecting circuit 110, a current comparing circuit 120 and an input voltage detecting circuit 130, which are applicable to the high-side switch HS and the low-side switch LS.

The input voltage detecting circuit 130 is connected to the first terminal of the high-side switch HS. The input voltage detecting circuit 130 detects the input voltage VIN received by the first terminal of the high-side switch HS, and converts the input voltage VIN that is detected into an input detection converted current IINFLG.

The output voltage detecting circuit 110 is connected to the second terminal of the low-side switch LS. The output voltage detecting circuit 110 detects the output voltage VOUT of the second terminal of the low-side switch LS, and converts the output voltage VOUT that is detected into an output detection converted current IOUTFLG.

A first input terminal of the current comparing circuit 120 is connected to the output voltage detecting circuit 110. A second input terminal of the current comparing circuit 120 is connected to the input voltage detecting circuit 130. An output terminal of the current comparing circuit 120 is connected to the control terminal of the low-side switch LS.

The current comparing circuit 120 compares the output detection converted current IOUTFLG from the output voltage detecting circuit 110 with the input detection converted current IINFLG from the input voltage detecting circuit 130 to generate a comparison current. The current comparing circuit 120 sets the low-side main control signal VPL according to the comparison current, and outputs the low-side main control signal VPL to the control terminal of the low-side switch LS.

For example, when the current comparing circuit 120 determines that the output detection converted current IOUTFLG is larger than the input detection converted current IINFLG (and a current difference between the output detection converted current IOUTFLG and the input detection converted current IINFLG is larger than a current difference threshold), the current comparing circuit 120 turns off the low-side switch LS.

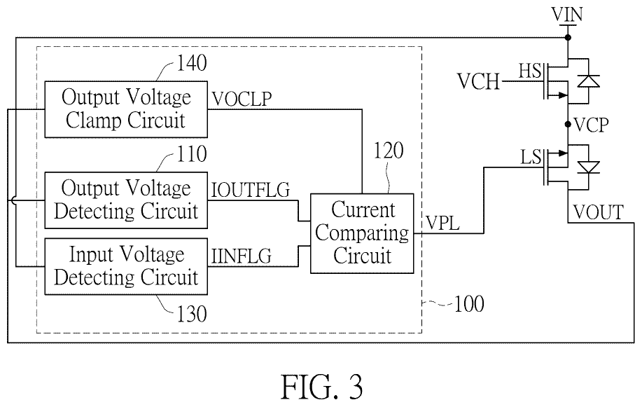

Reference is made to FIG. 3, which is a circuit diagram of a reverse current protection circuit according to a third embodiment of the present disclosure.

The descriptions of the third embodiment of the present disclosure that are the same as the descriptions of the second embodiment of the present disclosure are not repeated herein. A difference between the third and second embodiments of the present disclosure is that, as shown in FIG. 3, in the third embodiment, the main reverse current protecting circuit 100 of the reverse current protection circuit of the present disclosure not only includes the output voltage detecting circuit 110, the current comparing circuit 120 and the input voltage detecting circuit 130, but also includes an output voltage clamp circuit 140.

The output voltage clamp circuit 140 is connected to the second terminal of the low-side switch LS and a power input terminal of the current comparing circuit 120.

The output voltage clamp circuit 140, according to the output voltage VOUT of the second terminal of the low-side switch LS, outputs a power supply voltage VOCLP to the current comparing circuit 120 as power required for the current comparing circuit 120 controlling or clamping the output voltage VOUT of the second terminal of the low-side switch LS.

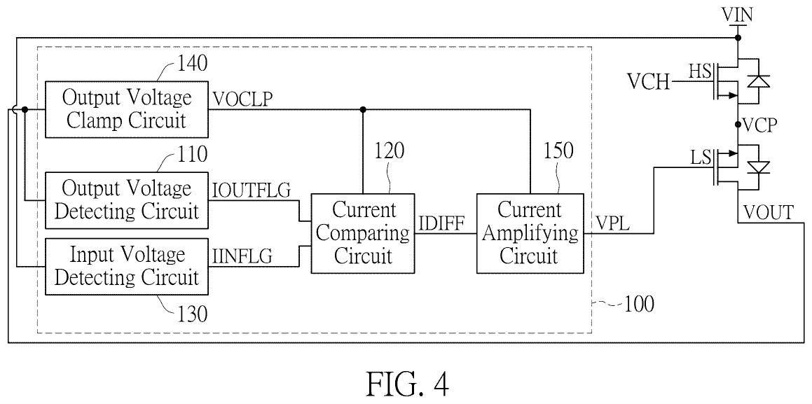

Reference is made to FIG. 4, which is a circuit diagram of a reverse current protection circuit according to a fourth embodiment of the present disclosure.

As shown in FIG. 4, in the fourth embodiment, the reverse current protection circuit of the present disclosure includes the main reverse current protecting circuit 100, which is applicable to the high-side switch HS and the low-side switch LS.

The descriptions of the fourth embodiment of the present disclosure that are the same as the descriptions of the second and third embodiments of the present disclosure are not repeated herein. A difference between the fourth and third embodiments of the present disclosure is that, as shown in FIG. 4, in the fourth embodiment, the reverse current protection circuit of the present disclosure not only includes the output voltage detecting circuit 110, the current comparing circuit 120, the input voltage detecting circuit 130 and the output voltage clamp circuit 140, but also includes a current amplifying circuit 150. In practice, the reverse current protection circuit shown in FIG. 2 may also include the current amplifying circuit 150.

As shown in FIG. 4, the current amplifying circuit 150 is connected between the output terminal of the current comparing circuit 120 and the control terminal of the low-side switch LS.

The current comparing circuit 120 compares the input detection converted current IINFLG with the output detection converted current IOUTFLG to output a comparison current IDIFF. For example, the current comparing circuit 120 may calculate the current difference between the output detection converted current IOUTFLG and the input detection converted current IINFLG, and may output the comparison current IDIFF having the current difference.

The current amplifying circuit 150 multiplies a current value of the comparison current IDIFF by a gain to generate a low-side control current amplified signal, and sets the low-side main control signal VPL according to the low-side control current amplified signal. The current amplifying circuit 150 outputs the low-side main control signal VPL to the control terminal of the low-side switch LS.

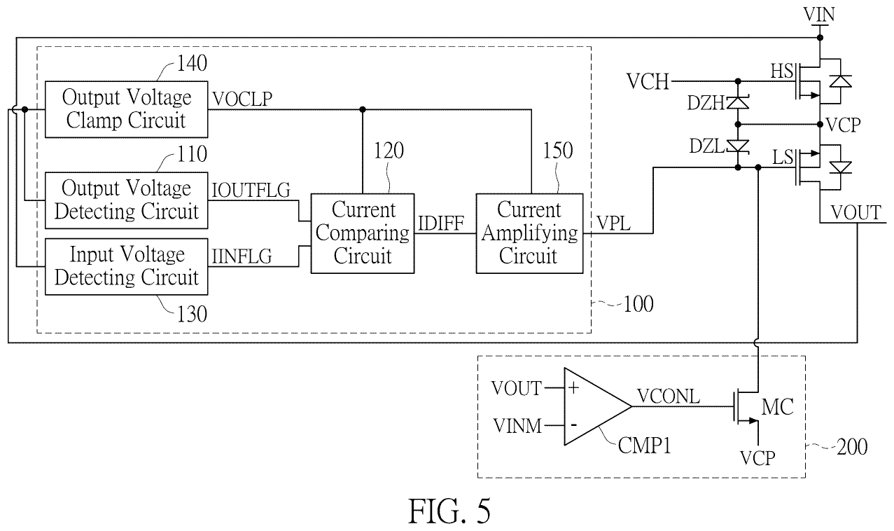

Reference is made to FIG. 5, which is a circuit diagram of a reverse current protection circuit according to a fifth embodiment of the present disclosure.

The descriptions of the fifth embodiment of the present disclosure that are the same as the descriptions of the second to fourth embodiments of the present disclosure are not repeated herein.

As shown in FIG. 5, in the fifth embodiment, the reverse current protection circuit of the present disclosure not only includes the main reverse current protecting circuit 100, but also includes an initial reverse current protection circuit 200 that is applicable to the high-side switch HS and the low-side switch LS.

The initial reverse current protection circuit 200 compares the output voltage VOUT of the second terminal of the low-side switch LS with an input detection modulation voltage VINM, and accordingly controls the low-side switch LS. The input detection modulation voltage VINM is equal to a sum of the input voltage VIN received by the first terminal of the high-side switch HS and a preset modulation voltage.

For example, the initial reverse current protection circuit 200 includes an initial comparator CMP1 and an initial transistor MC.

A first input terminal such as a non-inverting input terminal of the initial comparator CMP1 is connected to the second terminal of the low-side switch LS, and receives the output voltage VOUT from the second terminal of the low-side switch LS. A second input terminal such as an inverting input terminal of the initial comparator CMP1 is coupled to the input detection modulation voltage VINM.

A control terminal of the initial transistor MC is connected to an output terminal of the initial comparator CMP1. A second terminal of the initial transistor MC is coupled to a reference voltage VCP.

The initial comparator CMP1 compares the output voltage VOUT of the second terminal of the low-side switch LS with the input detection modulation voltage VINM to output an initial low-side control signal VCONL to the control terminal of the initial transistor MC.

When the output voltage VOUT of the second terminal of the low-side switch LS is lower than the input detection modulation voltage VINM, the initial comparator CMP1 outputs the initial low-side control signal VCONL at a non-trigged level such as a low level to the control terminal of the initial transistor MC for turning off the initial transistor MC. At this time, the initial reverse current protection circuit 200 does not switch the low-side switch LS.

Conversely, when the output voltage VOUT of the second terminal of the low-side switch LS is higher than the input detection modulation voltage VINM, the initial comparator CMP1 outputs the initial low-side control signal VCONL at a trigged level such as a high level to the control terminal of the initial transistor MC for turning on the initial transistor MC. As a result, the control terminal of the low-side switch LS is coupled to the reference voltage VCP at the low level through the initial transistor MC. At this time, the initial reverse current protection circuit 200 pulls down a voltage of the control terminal of the low-side switch LS such that the on-time of the low-side switch LS is reduced or the low-side switch LS is switched from an on-state to an off-state. As a result, the reverse current being larger than the reverse current threshold is prevented from flowing from the output voltage VOUT of the second terminal of the low-side switch LS sequentially through the low-side switch LS and the high-side switch HS to the input power source used to supply the input voltage VIN. Therefore, the input power source is prevented from being damaged by the reverse current.

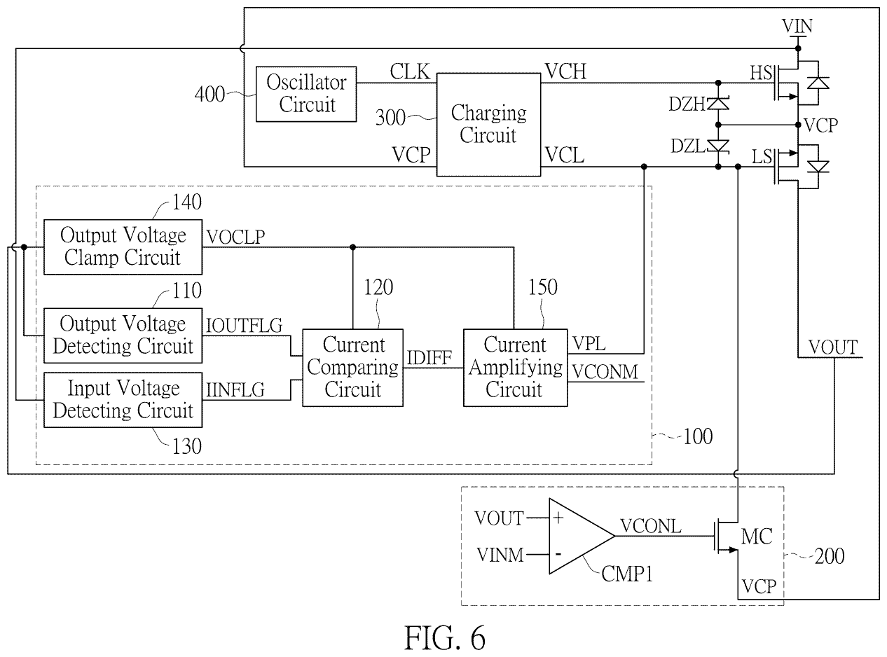

Reference is made to FIG. 6, which is a circuit diagram of a reverse current protection circuit according to a sixth embodiment of the present disclosure.

The descriptions of the sixth embodiment of the present disclosure that are the same as the descriptions of the second to fifth embodiments of the present disclosure are not repeated herein.

As shown in FIG. 5, in the sixth embodiment, the reverse current protection circuit of the present disclosure not only includes the main reverse current protecting circuit 100 and the initial reverse current protection circuit 200, but also includes the charging circuit 300 and the oscillator circuit 400. The charging circuit 300 and the oscillator circuit 400 are applicable to the high-side switch HS and the low-side switch LS. The charging circuit 300 is connected to the oscillator circuit 400, the control terminal of the high-side switch HS and the control terminal of the low-side switch LS.

The reverse current protection circuit of the present disclosure may further includes a high-side Zener diode DZH, a low-side Zener diode DZL or a combination thereof for realizing a voltage stabilization effect.

A cathode of the high-side Zener diode DZH is connected to the control terminal of the high-side switch HS. An anode of the high-side Zener diode DZH is connected to the second terminal of the high-side switch HS.

An anode of the low-side Zener diode DZL is connected to the first terminal of the low-side switch LS. A cathode of the low-side Zener diode DZL is connected to the control terminal of the low-side switch LS.

The oscillator circuit 400 may output a clock signal.

The charging circuit 300 outputs a high-side charging voltage VCH to the control terminal of the high-side switch HS and outputs a low-side charging voltage VCL to the control terminal of the low-side switch LS (according to the reference voltage VCP of the second terminal of the initial transistor MC).

The charging circuit 300 may, according to frequencies of the clock signal, control a frequency of outputting the high-side charging voltage VCH to the control terminal of the high-side switch HS and a frequency of outputting the low-side charging voltage VCL to the control terminal of the low-side switch LS.

That is, the charging circuit 300 and the oscillator circuit 400 are configured to supply appropriate power to the control terminal of the high-side switch HS and the control terminal of the low-side switch LS for reducing power consumption of the reverse current protection circuit of the present disclosure.

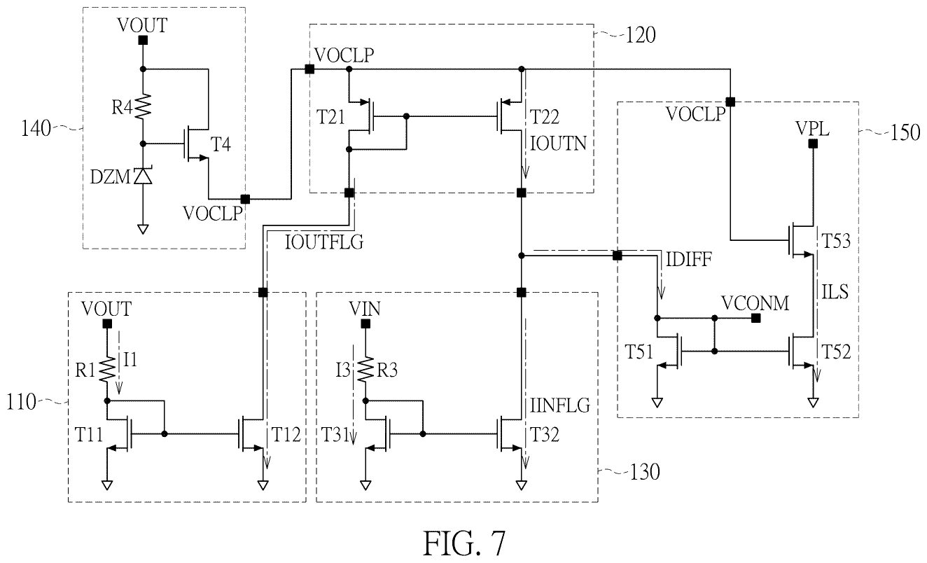

Reference is made to FIG. 7, which is a circuit diagram of a main reverse current protecting circuit included in a reverse current protection circuit according to a seventh embodiment of the present disclosure.

The output voltage detecting circuit 110 shown in FIG. 4 to FIG. 6 may include a first output transistor T11 and a second output transistor T12 as shown in FIG. 7. If necessary, the output voltage detecting circuit 110 shown in FIG. 4 to FIG. 6 may further include an output resistor R1 shown in FIG. 7.

The current comparing circuit 120 shown in FIG. 4 to FIG. 6 may include a first comparison transistor T21 and a second comparison transistor T22 as shown in FIG. 7.

The input voltage detecting circuit 130 as shown in FIG. 4 to FIG. 6 may include a first input transistor T31 and a second input transistor T32 as shown in FIG. 7. If necessary, the input voltage detecting circuit 130 as shown in FIG. 4 to FIG. 6 may further include an input resistor R3 shown in FIG. 7.

The output voltage clamp circuit 140 as shown in FIG. 4 to FIG. 6 may include a Zener diode DZM and a clamp transistor T4 as shown in FIG. 7. If necessary, the output voltage clamp circuit 140 as shown in FIG. 4 to FIG. 6 may further include a clamp resistor R4 shown in FIG. 7.

The current amplifying circuit 150 as shown in FIG. 4 to FIG. 6 may include a current input transistor T51 and a current output transistor T52 as shown in FIG. 7. If necessary, the current amplifying circuit 150 as shown in FIG. 4 to FIG. 6 may further include a second current output transistor T53 shown in FIG. 7.

A first terminal of the output resistor R1 of the output voltage detecting circuit 110 shown in FIG. 7 is connected to the second terminal of the low-side switch LS as shown in FIG. 4 to FIG. 6, and receives the output voltage VOUT from the second terminal of the low-side switch LS.

In the output voltage detecting circuit 110, a first terminal of the first output transistor T11 is connected to a second terminal of the output resistor R1. A second terminal of the first output transistor T11 is grounded.

An output current I1 flows from the output voltage VOUT of the second terminal of the low-side switch LS through the output resistor R1 to the first terminal of the first output transistor T11.

A control terminal of the second output transistor T12 is connected to the first terminal and a control terminal of the first output transistor T11. A second terminal of the second output transistor T12 is grounded. The output detection converted current IOUTFLG flows through a first terminal of the second output transistor T12. A ratio of the output detection converted current IOUTFLG flowing through the first terminal of the second output transistor T12 (that is an output terminal of the output voltage detecting circuit 110) to an output current I1 of the first terminal of the first output transistor T11 or the output resistor R1 (that is an input terminal of the output voltage detecting circuit 110) is 1:M, wherein M is a positive integer value.

A first terminal of the first comparison transistor T21 of the current comparing circuit 120 is coupled to the power supply voltage VOCLP. For example, the first terminal of the first comparison transistor T21 of the current comparing circuit 120 may obtain the power supply voltage VOCLP from the output voltage clamp circuit 140.

A first terminal of the clamp resistor R4 is connected to the second terminal of the low-side switch LS, and receives the output voltage VOUT from the second terminal of the low-side switch LS. A second terminal of the clamp resistor R4 is connected to a cathode of the Zener diode DZM. An anode of the Zener diode DZM is grounded. A control terminal of the clamp transistor T4 is connected to the cathode of the Zener diode DZM. A first terminal of the clamp transistor T4 is connected to the second terminal of the low-side switch LS.

A second terminal of the clamp transistor T4 of the output voltage clamp circuit 140 is connected to the first terminal of the first comparison transistor T21 and a first terminal of the second comparison transistor T22 of the current comparing circuit 120. The first terminal of the first comparison transistor T21 and the first terminal of the second comparison transistor T22 of the current comparing circuit 120 receive the power supply voltage VOCLP from the second terminal of the clamp transistor T4.

A second terminal of the first comparison transistor T21 of the current comparing circuit 120 is connected to the first terminal of the second output transistor T12 of the output voltage detecting circuit 110. The output detection converted current IOUTFLG flows through the second terminal of the first comparison transistor T21.

A control terminal of the second comparison transistor T22 of the current comparing circuit 120 is connected to the second terminal and a control terminal of the first comparison transistor T21. A ratio of a current value of the output detection converted current IOUTFLG flowing through the second terminal of the first comparison transistor T21 to a current value of a comparison output current IOUTN flowing through the second comparison transistor T22 is X:Y, wherein X and Y are positive integer values.

A first terminal of the input resistor R3 of the input voltage detecting circuit 130 shown in FIG. 7 is connected to the first terminal of the high-side switch HS as shown in FIG. 4 to FIG. 6, and receives the input voltage VIN to which the first terminal of the high-side switch HS is coupled.

As shown in FIG. 7, in the input voltage detecting circuit 130, a first terminal of the first input transistor T31 is connected to a second terminal of the input resistor R3, and a control terminal of the second input transistor T32 is connected to the first terminal and a control terminal of the first input transistor T31. A second terminal of the first input transistor T31 of the input voltage detecting circuit 130 and a second terminal of the second input transistor T32 are grounded.

A first terminal of the second input transistor T32 of the input voltage detecting circuit 130 is connected to a second terminal of the second comparison transistor T22 of the current comparing circuit 120.

The first terminal of the first input transistor T31 is used as an input terminal of the input voltage detecting circuit 130. The first terminal of the second input transistor T32 is used as an output terminal of the input voltage detecting circuit 130. A ratio of an input current I3 flowing through the input voltage detecting circuit 130 to the input detection converted current IINFLG flowing through the first terminal of the second input transistor T32 of the input voltage detecting circuit 130 is 1:N, wherein N is a positive integer value.

A first terminal of the current input transistor T51 of the current amplifying circuit 150 is connected to a node between the first terminal of the second input transistor T32 of the input voltage detecting circuit 130 and the second terminal of the second comparison transistor T22 of the current comparing circuit 120. A second terminal of the current input transistor T51 is grounded.

In the current amplifying circuit 150, a control terminal of the current output transistor T52 is connected to the first terminal and a control terminal of the current input transistor T51. A first terminal of the current output transistor T52 is connected to a second terminal of the second current output transistor T53. A second terminal of the current output transistor T52 is grounded.

A ratio of the current value of the comparison current IDIFF flowing through the first terminal of the current input transistor T51 to a current value of a low-side control current ILS flowing through the first terminal of the current output transistor T52 is 1:K, wherein K is a positive integer value.

A control terminal of the second current output transistor T53 of the current amplifying circuit 150 is coupled to the power supply voltage VOCLP, or is connected to the second terminal of the clamp transistor T4 of the output voltage clamp circuit 140 and receives the power supply voltage VOCLP from the second terminal of the clamp transistor T4.

A first terminal of the second current output transistor T53 included in the current amplifying circuit 150 of the output voltage detecting circuit 110 shown in FIG. 7 is connected to the control terminal of the low-side switch LS shown in FIG. 4 to FIG. 6 for controlling the voltage of the control terminal of the low-side switch LS.

It is worth noting that, the comparison output current IOUTN flowing through the second comparison transistor T22 is a sum of the input detection converted current IINFLG flowing through the first terminal of the second input transistor T32 and the comparison current IDIFF flowing through the first terminal of the current input transistor T51.

When the input voltage VIN received by the first terminal of the high-side switch HS reaches the zero value, the input detection converted current IINFLG flowing through the first terminal of the second input transistor T32 of the input voltage detecting circuit 130 reaches the zero value. At this time, the current value of the comparison current IDIFF flowing through the first terminal of the current input transistor T51 is equal to a current value of the comparison output current IOUTN flowing through the second comparison transistor T22. At this time, the comparison current IDIFF is larger than the zero current value such that a voltage VCONM of the first terminal of the current input transistor T51 is pulled up. The low-side control current ILS being larger the zero current value flows through the current output transistor T52 and the second current output transistor T53 to a ground. In other words, the current amplifying circuit 150 obtains the low-side control current ILS from the control terminal of the low-side switch LS such that the voltage of the control terminal of the low-side switch LS is reduced. As a result, the low-side switch LS is turned off. Therefore, the reverse current being larger than the reverse current threshold is prevented from flowing from the output voltage VOUT of the second terminal of the low-side switch LS sequentially through the low-side switch LS and the high-side switch HS to the input power source used to supply the input voltage VIN. The input power source is prevented from being damaged by the reverse current.

When the input voltage VIN is removed from the first terminal of the high-side switch HS such that the first terminal of the high-side switch HS is floating, a short circuit occurs in the input power source used to supply the input voltage VIN or the input voltage VIN is the zero value, the reverse current protection circuit of the present disclosure is capable of preventing the reverse current from flowing back to the input power source. Therefore, the input power source is not damaged and is able to normally supply the input voltage VIN such that the high-side switch HS and the low-side switch LS operate normally.

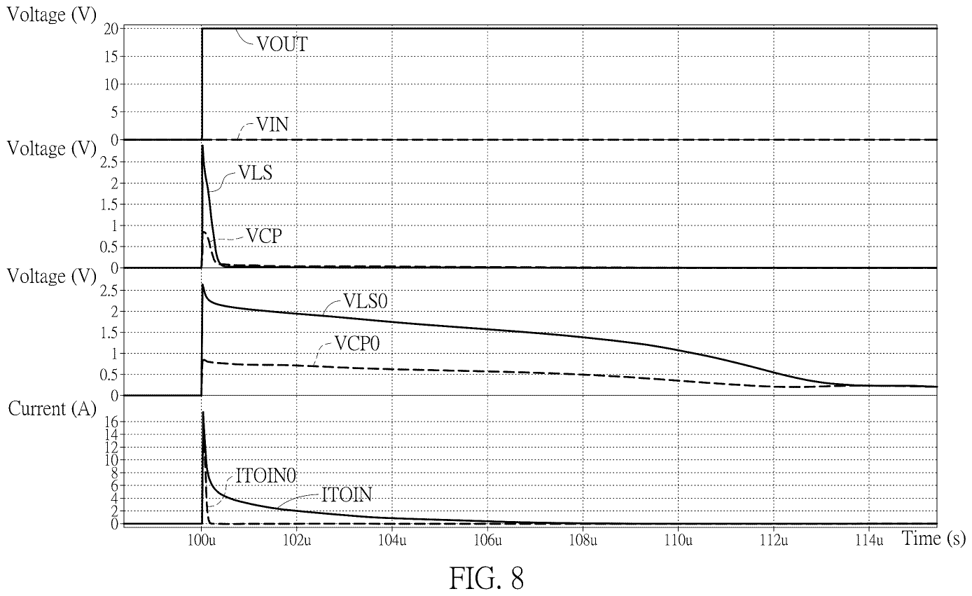

Reference is made to FIG. 8, which is a waveform diagram of signals of the reverse current protection circuit according to the first to seventh embodiments of the present disclosure.

As shown in FIG. 8, the input voltage VIN received by the first terminal of the high-side switch HS is the zero value, and the output voltage VOUT of the second terminal of the low-side switch LS is increased to too high a value.

If the initial reverse current protection circuit 200 but not the main reverse current protecting circuit 100 is disposed, the reference voltage VCP of the second terminal of the initial transistor MC of the initial reverse current protection circuit 200 and a voltage VLS0 of the control terminal of the low-side switch LS are slowly reduced. Under this condition, when the output voltage VOUT of the second terminal of the low-side switch LS is much higher than the input voltage VIN to which the first terminal of the high-side switch HS is coupled, the reverse current flows from the output voltage VOUT of the second terminal of the low-side switch LS through the first terminal of the high-side switch HS to the input power source used to supply the input voltage VIN. As a result, a reverse current ITOIN0 flowing to the input power source is increased to an excessive current value such that the input power source is damaged.

In contrast, if the main reverse current protecting circuit 100 of the reverse current protection circuit of the present disclosure is disposed, a voltage VLS of the control terminal of the low-side switch LS is quickly pulled down to the zero value for quickly turning off the low-side switch LS. The reverse current being larger than the reverse current threshold is prevented from flowing from the output voltage VOUT of the second terminal of the low-side switch LS sequentially through the low-side switch LS and the high-side switch HS to the input power source used to supply the input voltage VIN. As a result, a reverse current ITOIN flowing to the input power source is not increased to the excessive current value, thereby preventing the input power source from being damaged by the reverse current having the excessive current value. When the voltage VLS of the control terminal of the low-side switch LS is quickly pulled down, a voltage of the first terminal of the initial transistor MC of the initial reverse current protection circuit 200 is quickly reduced such that the reference voltage VCP of the second terminal of the initial transistor MC is quickly reduced.

In conclusion, the present disclosure provides the reverse current protection circuit. When the input voltage is removed from the first terminal of the high-side switch such that the first terminal of the high-side switch is floating or the short circuit occurs in the input power source used to supply the input voltage, the reverse current protection circuit of the present disclosure appropriately switches the low-side switch. The reverse current being larger than the reverse current threshold is prevented from flowing from the output voltage of the second terminal of the low-side switch sequentially through the low-side switch and the high-side switch to the input power source connected to the first terminal of the high-side switch. Therefore, a reverse current protection effect that the input power source is prevented from being damaged by the reverse current is achieved. In particular, when the reverse current protection effect is achieved, power consumption of the reverse current protection circuit of the present disclosure is much lower than that of conventional reverse current protection circuits.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A reverse current protection circuit, which is applicable to a high-side switch and a low-side switch, wherein a first terminal of the high-side switch is coupled to an input voltage, a control terminal of the high-side switch is coupled to a high-side charging voltage, and a first terminal of the low-side switch is connected to a second terminal of the high-side switch, the reverse current protection circuit comprising:
a main reverse current protecting circuit connected to a control terminal of the low-side switch, configured to detect the input voltage received by the first terminal of the high-side switch and an output voltage of a second terminal of the low-side switch, and configured to control the low-side switch according to the input voltage and the output voltage;
wherein, before a reverse current being larger than a reverse current threshold flows from the output voltage of the second terminal of the low-side switch sequentially through the low-side switch and the high-side switch to the input voltage, the main reverse current protecting circuit turns off the low-side switch.

2. The reverse current protection circuit according to claim 1, wherein the main reverse current protecting circuit includes:
an output voltage detecting circuit connected to the second terminal of the low-side switch, and configured to detect the output voltage and convert the output voltage into an output detection converted current;
an input voltage detecting circuit connected to the first terminal of the high-side switch, and configured to detect the input voltage and convert the input voltage into an input detection converted current; and
a current comparing circuit connected to the output voltage detecting circuit, the input voltage detecting circuit and the control terminal of the low-side switch, and configured to compare the output detection converted current with the input detection converted current to output a low-side main control signal to the control terminal of the low-side switch.

3. The reverse current protection circuit according to claim 2, wherein, when the current comparing circuit determines that the output detection converted current is larger than the input detection converted current, the current comparing circuit turns off the low-side switch.

4. The reverse current protection circuit according to claim 2, wherein the main reverse current protecting circuit further includes:
an output voltage clamp circuit connected to the second terminal of the low-side switch and the current comparing circuit, and configured to output a power supply voltage to the current comparing circuit according to the output voltage of the second terminal of the low-side switch.

5. The reverse current protection circuit according to claim 2, wherein the main reverse current protecting circuit further includes:
a current amplifying circuit connected between the current comparing circuit and the control terminal of the low-side switch, and configured to multiply the low-side main control signal by a gain to output a low-side control current amplified signal to the control terminal of the low-side switch.

6. The reverse current protection circuit according to claim 2, wherein the main output voltage detecting circuit includes:
a first output transistor, wherein a first terminal of the first output transistor is connected to the second terminal of the low-side switch, and a second terminal of the first output transistor is grounded; and
a second output transistor, wherein a control terminal of the second output transistor is connected to the first terminal and a control terminal of the first output transistor, a first terminal of the second output transistor is connected to the current comparing circuit, and a second terminal of the second output transistor is grounded;
wherein the current comparing circuit is configured to use a current flowing through the first terminal of the second output transistor as the output detection converted current.

7. The reverse current protection circuit according to claim 6, wherein the output voltage detecting circuit further includes:
an output resistor connected between the second terminal of the low-side switch and the first terminal of the first output transistor.

8. The reverse current protection circuit according to claim 6, wherein the input voltage detecting circuit includes:
a first input transistor, wherein a first terminal of the first input transistor is connected to the first terminal of the high-side switch, and a second terminal of the first input transistor is grounded; and
a second input transistor, wherein a control terminal of the second input transistor is connected to the first terminal and a control terminal of the first input transistor, a first terminal of the second input transistor is connected to the current comparing circuit, and a second terminal of the second input transistor is grounded;
wherein the current comparing circuit is configured to use a current flowing through the first terminal of the second input transistor as the input detection converted current.

9. The reverse current protection circuit according to claim 8, wherein the input voltage detecting circuit further includes:
an input resistor connected between the input voltage and the first terminal of the first output transistor.

10. The reverse current protection circuit according to claim 8, wherein the current comparing circuit includes:
a first comparison transistor, wherein a first terminal of the first comparison transistor is coupled to a power supply voltage, and a second terminal of the first comparison transistor is connected to the first terminal of the second output transistor; and
a second comparison transistor, wherein a control terminal of the second comparison transistor is connected to the second terminal and a control terminal of the first comparison transistor, a first terminal of the second comparison transistor is coupled to the power supply voltage, and a second terminal of the second comparison transistor is connected to the first terminal of the second input transistor.

11. The reverse current protection circuit according to claim 10, wherein the main reverse current protecting circuit further includes:
a current amplifying circuit including:
a current input transistor, wherein a first terminal of the current input transistor is connected to a node between the second terminal of the second comparison transistor and the first terminal of the second input transistor, and a second terminal of the current input transistor is grounded; and
a current output transistor, wherein a control terminal of the current output transistor is connected to the first terminal and a control terminal of the current input transistor, a first terminal of the current output transistor is connected to the control terminal of the low-side switch, and a second terminal of the current output transistor is grounded.

12. The reverse current protection circuit according to claim 11, wherein the current amplifying circuit further includes:
a second current output transistor, wherein a control terminal of the second current output transistor is coupled to the power supply voltage, a first terminal of the second current output transistor is connected to the control terminal of the low-side switch, and a second terminal of the second current output transistor is connected to the first terminal of the current output transistor.

13. The reverse current protection circuit according to claim 12, wherein the main reverse current protecting circuit further includes:
an output voltage clamp circuit including:
a Zener diode, wherein a cathode of the Zener diode is connected to the second terminal of the low-side switch, and an anode of the Zener diode is grounded; and
a clamp transistor, wherein a control terminal of the clamp transistor is connected to the cathode of the Zener diode, a first terminal of the clamp transistor is connected to the second terminal of the low-side switch, and a second terminal of the clamp transistor is connected to the first terminal of the first comparison transistor, the first terminal of the second comparison transistor and the control terminal of the second current output transistor.

14. The reverse current protection circuit according to claim 13, wherein the output voltage clamp circuit further includes:
a clamp resistor connected between the cathode of the Zener diode and the second terminal of the low-side switch.

15. The reverse current protection circuit according to claim 1, further comprising:
an initial reverse current protection circuit configured to compare the output voltage with an input detection modulation voltage and accordingly control the low-side switch;
wherein the input detection modulation voltage is equal to a sum of the input voltage and a preset modulation voltage.

16. The reverse current protection circuit according to claim 15, wherein the initial reverse current protection circuit includes:
an initial comparator, wherein a first input terminal of the initial comparator is connected to the second terminal of the low-side switch, and a second input terminal of the initial comparator is coupled to the input detection modulation voltage; and
an initial transistor, wherein a control terminal of the initial transistor is connected to an output terminal of the initial comparator, a first terminal of the initial transistor is connected to the control terminal of the low-side switch, and a second terminal of the initial transistor is coupled to a reference voltage.

17. The reverse current protection circuit according to claim 1, further comprising:
a charging circuit connected to the control terminal of the high-side switch and the control terminal of the low-side switch, and configured to output the high-side charging voltage to the control terminal of the high-side switch and output a low-side charging voltage to the control terminal of the low-side switch.

18. The reverse current protection circuit according to claim 17, further comprising:
an oscillator circuit connected to the charging circuit, and configured to output a clock signal to the charging circuit;
wherein the charging circuit is configured to control a frequency of outputting the high-side charging voltage and a frequency of outputting the low-side charging voltage according to frequencies of the clock signal.
